(19) United States
(12) Patent Application Publication
(10) Pub. No.: US 2026/0127335 A1
(43) Pub. Date: May 7, 2026

(54) METHOD FOR PREDICTING A TIME COURSE OF A PHYSICAL TARGET VARIABLE BY MEANS OF A MACHINE LEARNING MODEL

(71) Applicant: Robert Bosch GmbH, Stuttgart (DE)

(72) Inventors: Sebastian Gerwinn, Leonberg (DE); Martin Schiegg, Korntal-Muenchingen (DE); Michal Moshkovitz, Tel-Aviv (IL)

(21) Appl. No.: 19/375,686

(22) Filed: Oct. 31, 2025

(30) Foreign Application Priority Data
Nov. 4, 2024 (EP) 24 21 0615.1

(51) Int. Cl. G06F 30/20

(52) U.S. Cl. CPC G06F 30/20

(57) ABSTRACT

A method for predicting a time course of a physical target. The method includes: providing multivariate sensor data including, for each of a plurality of physical variables, respective sensor data representing a time course of the physical variable, wherein each physical variable is assigned a respective text description describing it and its measurement environment; for each physical variable: dividing the respective sensor data into a respective plurality of sensor data segments; for each sensor data segment of the plurality of sensor data segments: determining a respective sensor data segment representation representing the sensor data segment and having a predefined dimension, determining a respective input element using the respective sensor data segment representation, time-related position information representing a position of the sensor data segment within the time period, and the respective text description of the physical variable; predicting the time course of the physical target variable.

### CROSS REFERENCE

The present application claims the benefit under 35 U.S.C. § 119 of Europe Patent Application No. EP 24 21 0615.1 filed on Nov. 4, 2024, which is expressly incorporated herein by reference in its entirety.

### BACKGROUND INFORMATION

For various technical (e.g., physical or chemical) processes, it may be desirable to predict a time course of a physical variable based on multivariate time series data of other physical variables and/or to predict an anomaly based on the multivariate time series data of multiple physical variables. For example, it may be desirable to predict a state of health or hydrogen loading of a fuel cell based on a time course of current and voltage, or in the case of a drilling machine, to predict which material is being drilled based on a time course of current and voltage, or to predict an anomaly based on the time course of current and voltage, etc. Typically, a machine learning model can be trained for exactly one use case (e.g., for predicting the state of health of the fuel cell).

### SUMMARY

The present invention relates to a method for predicting a time course of a physical target variable using a machine learning model based on multivariate sensor data, wherein the multivariate sensor data may be irregularly sampled sensor data. If sensor data are acquired from different sensors, they may have different sampling rates. Data points may also be missing from some sensor data (e.g., due to a measurement error or because they are removed due to excessive uncertainty, etc.). Time periods in which sensor data are available may also have different durations. Illustratively, it is possible that not every data point in first sensor data can be bijectively assigned to a data point in second sensor data differing from the first sensor data.

The method according to the present invention described herein allows for the prediction of the time course of the physical target variable even in such cases of irregular sensor data. According to an example embodiment of the present invention, this is achieved, for example, by dividing the sensor data into sensor data segments and then determining a respective sensor data segment representation for each sensor data segment, which representation has the same predefined dimension for all sensor data segments. Thus, the dimension of the sensor data segment representation is independent of the regularity (e.g., the sampling rate, the presence of data points, etc.) of the data points in the sensor data segment.

The machine learning model of the present invention described herein can also have been trained to predict a respective physical target variable of a plurality of different tasks with at least partially different physical variables. This allows, for example, the physical laws that apply across the various tasks to be efficiently learned. Such training is only possible because the method described herein can process irregular multivariate sensor data.

Various aspects pf the present invention relate to a method for predicting a time course of a physical target variable by means of a machine learning model. According to an example embodiment of the present invention, the method comprises: providing multivariate sensor data assigned to a time period and comprising, for each physical variable of a plurality of physical variables, respective sensor data representing a time course of the physical variable within the time period, wherein each physical variable is assigned a respective text description describing the physical variable (and optionally also a measurement environment in which the respective sensor data were acquired) (as text); for each physical variable of the plurality of physical variables: dividing the respective sensor data into a respective plurality of (e.g., disjoint) sensor data segments; for each sensor data segment of the plurality of sensor data segments: determining a respective sensor data segment representation representing the sensor data segment and having (independently of a number of data points of the sensor data segment) a predefined dimension, determining a respective input element using the respective sensor data segment representation, time-related position information representing a (e.g., temporal) position of the sensor data segment within the time period, and the respective text description of the physical variable; predicting the time course of the physical target variable by means of the machine learning model in response to an input of all input elements and at least one target variable query representing a (e.g., temporal) position of the time course to be predicted, within the time period and a text description of the physical target variable, into the machine learning model.

Various exemplary embodiments of the present invention are specified below.

Example 1 is the method for predicting the time course of the physical target variable by means of the machine learning model as described above.

Example 2 is configured according to example 1, wherein the respective plurality of sensor data segments of at least one physical variable comprises at least two sensor data segments with a different number of data points.

By mapping each sensor data segment to the respective sensor data segment representation with the predefined dimension, all sensor data segment representations have this predefined dimension regardless of the dimension of the sensor data segments, as a result of which the sensor data segments can have different dimensions (e.g., durations, number of data points (e.g., due to different sampling rates), scalar values, and even no values at all). Illustratively, the method can predict a time course of a target variable even for heterogeneous, multivariate sensor data.

Example 3 is configured according to example 1 or 2, wherein the time-related position information represents a start time and an end time within the time period.

Since the method described herein allows for a different number of data points for each sensor data segment, in addition to the start time, this time period (e.g., specified by the end time) can also be specified by means of the time-related position information.

Example 4 is configured according to one of examples 1 to 3, wherein the machine learning model comprises a transformer model whose encoder and/or decoder comprises an attention layer to which all input elements (i.e., each input element of each physical variable) are fed.

By feeding all input elements (and not just the input elements in the dimension of physical variables or in the time dimension) to the attention unit, the machine learning model can take more complex dependencies into account (e.g., due to previous training), thereby increasing prediction accuracy. This also allows the use of heterogeneous sensor data elements, such as scalar values and/or missing values in combination with time series.

Example 5 is configured according to one of examples 1 to 4, wherein the respective sensor data segment representation for a sensor data segment is determined by means of a (multi-head) attention unit having a learned sensor-data-segment-specific parameter vector as the query and the sensor data segment as the key and as the value; and/or wherein the respective input element is determined using the respective sensor data segment representation, a respective position representation, and the respective text description of the physical variable, wherein the position representation is determined by means of a (multi-head) attention unit having a learned position-specific parameter vector as the query and the time-related position information as the key and as the value.

Example 6 is configured according to one of examples 1 to 5, wherein the machine learning model comprises a transformer model whose one or more attention layers in the encoder and/or decoder comprise a (multi-head) attention unit to which the target variable query is fed.

For example, no trained free parameter is required as input, allowing the machine learning model to determine the prediction with reduced computational effort. Furthermore, training such a free parameter is not required during training, thus reducing the computational effort during training (and thus the time required for this purpose). Because the target variable query includes the text description of the physical target variable, the accuracy of the prediction is significantly increased.

Example 7 is a method for controlling a technical (e.g., physical or chemical) process, the method comprising: predicting the time course of the physical target variable according to one of examples 1 to 6 using provided multivariate sensor data; and controlling the technical process, taking into account the prediction.

Example 8 is a control device configured to carry out the method according to example 7.

Example 9 is a system comprising: a device configured to carry out the technical process; one or more sensors for acquiring the multivariate sensor data; and the control device according to example 8 for controlling the technical process.

Example 10 is a data processing unit configured to carry out the method according to one of examples 1 to 6.

Example 11 is a computer program comprising commands that, when executed by a processor, cause the processor to carry out the method according to one of examples 1 to 7.

Example 12 is a computer-readable medium storing commands that, when executed by a processor, cause the processor to carry out the method according to one of examples 1 to 7.

### BRIEF DESCRIPTION OF THE DRAWINGS

In the figures, similar reference signs generally refer to the same parts throughout the various views. The figures are not necessarily true to scale, with emphasis instead generally being placed on the representation of the principles of the present invention. In the following description, various aspects of the present invention are described with reference to the figures.

FIG. 1 shows a flowchart of a method for predicting a time course of a physical target variable according to various aspects, according to an example embodiment of the present invention.

FIG. 2 shows an exemplary system on which the method can be carried out, according to the present invention.

FIG. 3 shows a detected time course of an exemplary physical variable and a time course of a physical target variable to be predicted, according to the present invention.

FIG. 4 shows a determination of an input element according to various aspects of the present invention.

FIG. 5 shows a prediction of the time course of the physical target variable by means of a machine learning model according to various aspects of the present invention.

FIG. 6 shows an attention layer with single-stage attention according to various aspects of the present invention.

FIG. 7 shows a query-based routing example for two-stage attention, according to an example embodiment of the present invention.

### DETAILED DESCRIPTION OF EXAMPLE EMBODIMENTS

The following detailed description relates to the figures, which show, by way of explanation, specific details and aspects of this disclosure in which the present invention can be carried out. Other aspects may be used, and structural, logical, and electrical changes may be carried out without departing from the scope of protection of the present invention. The various aspects of this disclosure are not necessarily mutually exclusive, since some aspects of this disclosure may be combined with one or more other aspects of this disclosure to form new aspects.

Various examples are described in more detail below.

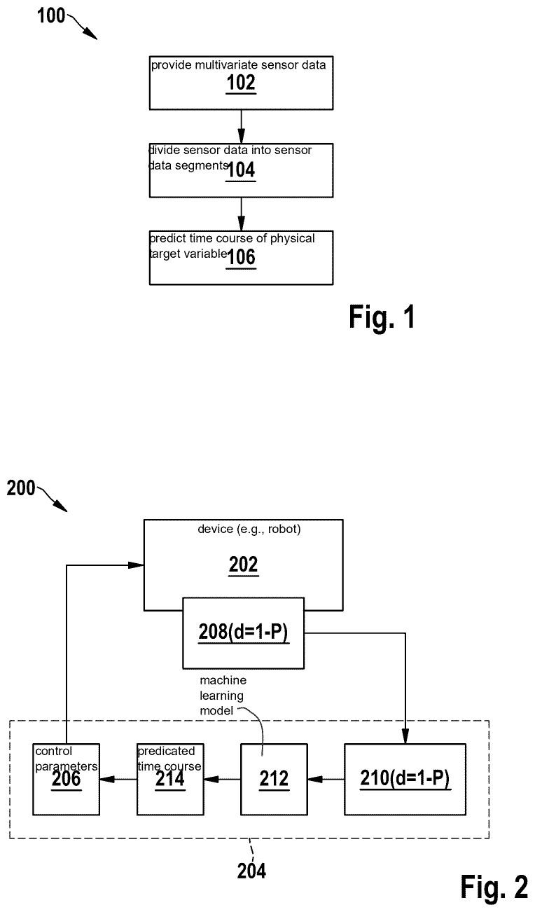

FIG. 1 shows a flowchart of a method 100 for predicting a time course of a physical target variable according to various aspects.

The method 100 may comprise (in 102) providing multivariate sensor data assigned to a time period and comprising, for each physical variable of a plurality of physical variables, respective sensor data representing a time course of the physical variable within the time period. Each physical variable can be assigned a respective text description describing the physical variable and a measurement environment in which the respective sensor data were acquired (e.g., as text).

The method 100 may comprise (in 104), for each physical variable of the plurality of physical variables, dividing the respective sensor data into a respective plurality of (e.g., disjoint) sensor data segments. Furthermore, the method 100 may then comprise, for each sensor data segment of the plurality of sensor data segments, determining a respective sensor data segment representation representing the sensor data segment and having a predefined dimension, and determining a respective input element using the respective sensor data segment representation, time-related position information representing a (e.g., temporal) position of the sensor data segment within the time period, and the respective text description of the physical variable.

The method 100 may comprise (in 106) predicting the time course of the physical target variable by means of the machine learning model in response to an input of all input elements and at least one target variable query representing a (e.g., temporal) position of the time course to be predicted, within the time period and a text description of the physical target variable, into the machine learning model.

The method can be carried out by one or more computers with one or more data processing units. The term “data processing unit” may be understood as any type of entity that allows for processing of data or signals. The data or signals can be treated, for example, according to at least one (i.e., one or more than one) specific function which is carried out by the data processing unit. A data processing unit can comprise or be formed from an analog circuit, a digital circuit, a logic circuit, a microprocessor, a microcontroller, a central processing unit (CPU), a graphics processing unit (GPU), a digital signal processor (DSP), an integrated circuit of a programmable gate array (FPGA), or any combination thereof. Any other way of implementing the particular functions described in more detail herein may also be understood as a data processing unit or logic circuit assembly. One or more of the method steps described in detail here can be carried out (e.g., implemented) by a data processing unit by one or more specific functions that are carried out by the data processing unit.

The method is therefore in particular computer-implemented according to various embodiments.

FIG. 2 shows a system 200 according to various aspects. The system 200 may comprise a device 202 configured to carry out a technical process. According to various aspects, the device 202 may be a robotic device (robot for short), such as an industrial robot in the form of a robot arm for moving, assembling, or processing a workpiece, for bin picking, a manufacturing robot, a maintenance robot, a household robot, a medical robot, a vehicle (e.g., an at least partially automated vehicle), a household appliance, a craft tool (e.g., a drill), a production machine, a personal assistant, an access control system, etc., as well as any other type of robotic device. According to various aspects, the technical process can be a physical or chemical process, such as a manufacturing process (e.g., manufacturing a product or intermediate product), a machining process (e.g., machining a workpiece), a control process (e.g., moving a robot arm), an adjustment process (e.g., calibrating a measuring apparatus), etc.

The system 200 may comprise a control device 204 configured to control the technical process (e.g., according to one or more control parameters 206). The term “control device” (also referred to as “controller”) can be understood as any type of logical implementation unit that may include, for example, a circuit and/or a processor capable of executing software, firmware, or a combination thereof stored in a storage medium and can issue the instructions, e.g., to an actuator in the present example. The control device may be configured, for example, by program code (e.g., software) to control the operation of the system 200.

According to various aspects, multivariate time series of sensor data (i.e., multivariate sensor data) can be acquired over a time period. Illustratively, the multivariate sensor data 210 (d=1 to P) may represent, for each physical variable d of a plurality of P physical variables (where P can be any integer greater than or equal to one), a respective time course of the physical variable within the time period. A sensor 208(d) for acquiring sensor data may, for example, be a temperature sensor, a concentration sensor for sensing one or more elements, a pressure sensor, etc. The sensor data of a physical variable may be not only an output variable of the technical process but also an input variable that is applied according to the one or more control parameters 206 for controlling the technical process, such as an applied voltage and/or a current (e.g., resulting from an applied voltage). The sensor data of a physical variable can be acquired in-situ or ex-situ. For example, after the technical process has been carried out (e.g., ex-situ), a property of a manufactured product can be detected (as sensor data). Consequently, it is understood that the multivariate sensor data can comprise time series of physical variables that are related in some way to the technical process.

According to various aspects, the control device 204 can be configured to implement a machine learning model 212. The machine learning model 212 can be configured to predict a (e.g., unrecorded) time course 214 of (at least) one physical target variable using the multivariate sensor data 210 (d=1 to D). The control device 204 can be configured to adjust the one or more control parameters 206, taking the predicted time course 214 of the physical target variable into account (i.e., to control the technical process). According to various aspects, the control device 204 can be configured to determine an anomaly based on the predicted time course 214 of the physical target variable and to control the technical process accordingly (e.g., to stop and output a signal informing a user of the device 202 of the anomaly).

Various aspects of the method 100 are described in more detail below, for the technical system 200 as an example.

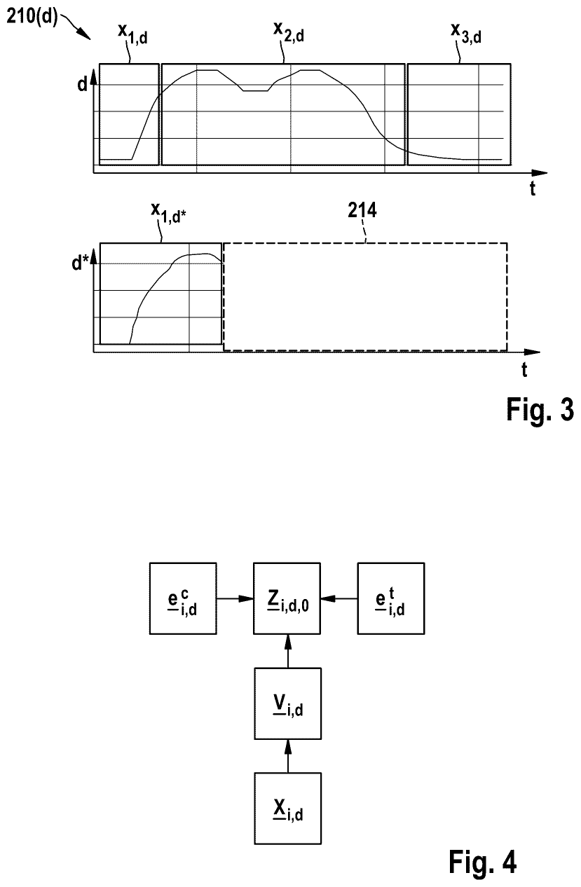

FIG. 3 shows a detected time course 210(d) of an exemplary physical variable d within a time period, a detected time course of the target physical variable d* within a portion of the time period, and the time course 214 of the target physical variable d* to be predicted.

In 104, the sensor data of each physical variable d can be divided into one or more (e.g., a plurality of) (e.g., disjoint) sensor data segments

$${x}_{i , d}^{( s )} ∈ {ℝ}^{{L}_{i , d}} .$$

Illustratively, the time course 210(d) of each physical variable d can be divided into one or more time periods

$${x}_{i , d}^{( s )} .$$

Here, L_{i,d} can specify the number of sensor data segments and can be greater than or equal to one. According to various aspects, the sensor data segments

$${x}_{i , d}^{( s )}$$

can have a different number of data points. The number of data points can also be referred to as the number of time points, wherein each time point is assigned a data point. Each sensor data segment

$${x}_{i , d}^{( s )}$$

can therefore be assigned a time period

$${τ}_{k , i , d}^{( s )}$$

with a start time and an end time within the time period of the sensor data.

$${τ}_{k , i , d}^{( s )}$$

can also be referred to as time-related position information since this indicates the temporal position within the time period. This time period can be represented, for example, by a multidimensional feature vector. For example, each physical variable d can be or become assigned a time-related position vector

$${τ}_{i , d}^{( s )} = \{ {τ}_{k , i , d}^{( s )} \vert k = 1 , … , {L}_{i , d} \} .$$

For illustration, in various aspects, the physical variables of the plurality of physical variables are referred to as a channel or as a channel dimension c. Each physical variable d can be assigned a respective text description TB. The text description can describe the physical variable d and a measurement environment in which the corresponding sensor data were acquired (e.g., as text). A text description of a physical variable d described herein can, for example, include the physical variable itself, a description of its signal, one or more pieces of information regarding a sensor by means of which the sensor data were acquired, etc.

In some aspects, at least one time period

$${x}_{i * , d *}^{( s )}$$

may be associated with the physical target variable d*. In this case, data points of the physical target variable d* within the time period 214 can be considered missing values. In one example, the multivariate sensor data may be considered future sensor data, and the prediction of the time course of the physical target variable d* may be a prediction of the future course. In other aspects, no sensor data of the physical target variable d* may be present, for example, if a complete signal of the physical target variable d* is to be generated. This is also referred to as a virtual sensor. Illustratively, in this case, all data points of the physical target variable d* can be considered missing values.

According to various aspects, a respective input element Z_{i,d,0} can be determined for each sensor data segment

$${x}_{i , d}^{( s )} .$$

FIG. 4 shows a determination of an input element Z_{i,d,0} for a sensor data segment

$${x}_{i , d}^{( s )}$$

according to various aspects.

According to various aspects, a sensor data segment representation V_{i,d} can be determined which represents the sensor data segment

$${x}_{i , d}^{( s )}$$

and has a predefined dimension D (i.e., V_{i,d}∈ [symbol] ^{D}) regardless of the time length of the sensor data segment

$${x}_{i , d}^{( s )} ) .$$

For example, the sensor data segment representation for a sensor data segment can be determined by means of a (multi-head) (standard) attention unit (MSA(Q,K,V) with a query Q, key K, and value V as in reference [2], for example), which has a learned sensor-data-segment-specific parameter vector

$${e}_{CLS}^{Value}$$

as the query and the sensor data segment

$${x}_{i , d}^{( s )}$$

as the key and as the value, according to

$${V}_{i , d} = M SA ( {e}_{CLS}^{Value} , {x}_{i , d}^{( s )} , {x}_{i , d}^{( s )} ) .$$

Illustratively, the sensor-data-segment-specific parameter vector

$${e}_{CLS}^{Value}$$

can be used as a query for all sensor data segments

$${x}_{i , d}^{( s )}$$

according to which the respective sensor data segment

$${x}_{i , d}^{( s )}$$

is mapped to the sensor data segment representation V_{i,d} with the specified dimension D.

Although MSA is sometimes used to denote “multi-head self-attention,” where the query Q, the key K, and the value V are the same (i.e., Q=K=V), it is understood that MSA is used herein for a multi-head standard attention unit (multi-head standard attention for short), and that Q, K, and V can also be different from one another.

The learning of such a parameter vector e_{CLS} is described (for training language models), for example, in J. Devlin et al.: “BERT: Pre-training of Deep Bidirectional Transformers for Language Understanding,” arXiv:1810.04805, 2019 (hereinafter referred to as reference [1]), in which the parameter vector e_{CLS} is referred to as a special classification token CLS.

The sensor-data-segment-specific parameter vector

$${e}_{CLS}^{Value}$$

can have the dimension D (i.e., have a number of D parameters). The dimension D described herein may be adjustable by a user according to various aspects.

The input element Z_{i,d,0} can be determined using the sensor data segment representation V_{i,d}, an associated position representation

$${e}_{i , d}^{t} ,$$

and a text representation

$${e}_{i , d}^{c} ,$$

for example, according to

$${Z}_{i , d , 0} = {V}_{i , d} + {e}_{i , d}^{t} + {e}_{i , d}^{c} .$$

The text representation

$${e}_{i , d}^{c}$$

can represent the associated text description of the physical variable d. For example, the control device 204 may be configured to implement a text encoder f(⋅) that is configured to map the text description (TB) to a text embedding e_{signal_d} (i.e., e_{signal_d}=f(TB)). The text encoder f(⋅) may, for example, have been trained as an encoder of a language model. The control device 204 can be configured to map the text embedding e_{signal_d}∈ [symbol] ^{D}^{ₜₑₓₜ} to the text representation

$${e}_{i , d}^{c}$$

$$( i . e . , {e}_{i , d}^{c} = {E}^{c} {e}_{signal \_ d} )$$

using a (e.g., learnable M×Dₜₑₓₜ-dimensional) matrix E^{c}. Illustratively,

$${e}_{i , d}^{c}$$

is a vector that depends on the text description of the physical variable d. Use of the text representation

$${e}_{i , d}^{c}$$

allows for the direct application of an existing model to a changed set of physical (input and/or output) variables.

The position representation

$${e}_{i , d}^{t}$$

may, in some aspects, be determined according to

$${e}_{i , d}^{t} = {f}^{definite time points} ( \{ {τ}_{k , i , d} \vert k = 1 , … , T \} )$$

using a predefined number T of minimum time points that are guaranteed to be available within a segment (e.g., due to minimum segment length T). In contrast, the position representation

$${e}_{i , d}^{t}$$

can advantageously be determined in other aspects by means of a (multi-head) attention unit MSA, which has a learned position-specific parameter vector

$${e}_{CLS}^{t}$$

as the query and the time-related position information

$${τ}_{i , d}^{( s )}$$

as the key and as the value, i.e.,

$${e}_{i , d}^{t} = MSA ( {e}_{CLS}^{t} , {τ}_{i , d}^{( s )} , {τ}_{i , d}^{( s )} ) .$$

In this way, the position representation

$${e}_{i , d}^{t}$$

has additional information, thereby increasing the accuracy of the machine learning model 212. Like the sensor-data-segment-specific parameter vector

$${e}_{CLS}^{Value} ,$$

the position-specific parameter vector

$${e}_{CLS}^{t}$$

can have the dimension D and can be used for all sensor data segments.

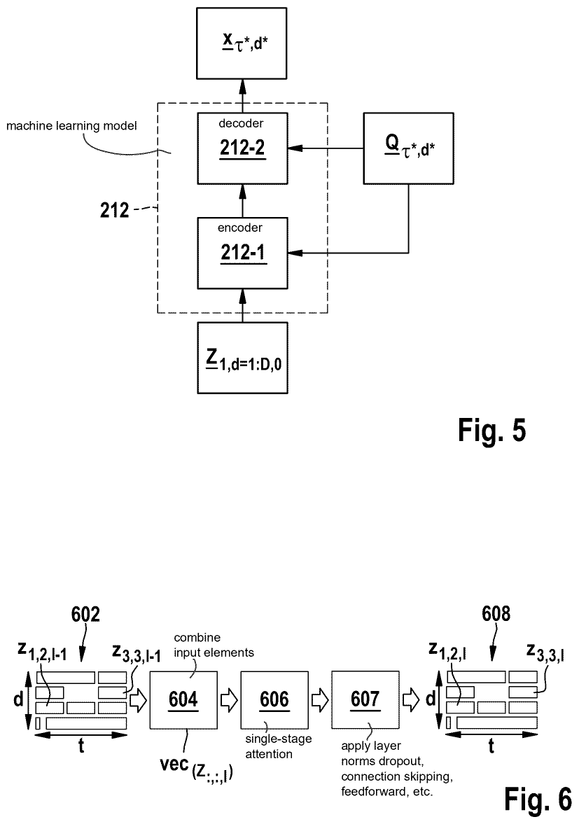

FIG. 5 shows a prediction of the time course 214 x_{τ*,d*} of the physical target variable d* by means of the machine learning model 212 according to various aspects.

According to various aspects, the machine learning model 212 may comprise or be a transformer model. The transformer model may comprise an encoder 212-1 and a decoder 212-2. An exemplary transformer model is described in Y. Zhang et al.: “Crossformer: Transformer utilizing cross-dimension dependency for multivariate time series forecasting,” International Conference on Learning Representations ICLR, 2022, 2019 (referred to herein as reference [2]). However, the transformer model described in reference [2] requires the use of regular multivariate sensor data (i.e., equal sampling rates, no missing values, etc.) to achieve satisfactory accuracy, since, in reference [2], all segment lengths must be equal and temporal information is not taken into account. In addition, the transformer model described in reference [2] can only predict time courses of predefined time lengths since the position encodings are learned. Furthermore, (since no text description is used,) no adaptation for other physical variables is possible. For the sake of brevity, differences from the transformer model described in reference [2] are described in particular below, and for other aspects, reference is made to reference [2].

An encoder 212-1 and/or decoder 212-2 described herein may comprise multiple attention layers l. The input elements Z_{i=1:L}_{_{i,d}}_{,d=1:P,l=0} can be fed to a first attention layer in the encoder 212-1, l=1. Each attention layer l can have an attention MSA that maps the input element Z_{i=1:L}_{_{i,d}}_{,d=1:P,l-1} of the attention layer l to an output vector \tilde{Z}_{i=1:L}_{_{i,d}}_{,d=1:P,l} according to \tilde{Z}_{i=1:L}_{_{i,d}}_{,d=1:P,l}=MSA(Z_{i=1:L}_{_{i,d}}_{,d=1:P,l-1},Z_{i=1:L}_{_{i,d}}_{,d=1:P,l-1},Z_{i=1:L}_{_{i,d}}_{,d=1:P,l-1}). The output vector Ź_{i=1:L}_{_{i,d}}_{,d=1:P,l} of the attention layer l can then follow the transformer architecture with the layer norms dropout, connection skipping, feedforward, etc. (see, for example, reference [2]), thereby determining the output element Z_{i=1:L}_{_{i,d}}_{,d=1:P,l} of the attention layer l, which is then the input element Z_{i=1:L}_{_{i,d}}_{,d=1:P,l} of the subsequent attention layer l+1.

Illustratively, \tilde{Z}_{:,:,l} can specify an intermediate result within an attention layer l, and Z_{:,:,l} can specify a result between two consecutive attention layers l, l+1.

According to various aspects, each attention layer l* in the encoder 212-1 and/or decoder 212-2 can have exactly one attention unit (i.e., single-stage attention), followed by layer norms dropout, connection skipping, feedforward, etc.), to which all input elements Z_{i=1:L}_{_{i,d}}_{,d=1:P,l*-1} are fed. For example, the first attention layer l=1 of the encoder 212-1 is fed the input elements Z_{i=1:L}_{_{i,d}}_{,d=1:P,0}. The first attention layer of the decoder 212-2 can be fed the input elements Z_{i=1:L}_{_{i,d}}_{,d=1:P,1} from the encoder 212-1 in addition to the target variable query (Q). In contrast, reference [2] uses two-stage attention (both in the encoder and the decoder), in which the time dimension (with time t) is processed in a first attention unit (i.e., the first stage) (followed by layer norms dropout, connection skipping, feedforward, etc.), and the channel dimension is processed in a second attention unit (i.e., the second stage) (also followed by layer norms dropout, connection skipping, feedforward, etc.). By using single-stage attention (MSA^{osa}), more complex dependencies between the different sensor data can be taken into account. For example, in the case of two-stage attention, features that depend on observations in different time periods in different channels cannot be learned within a single attention layer (and thus cannot be exploited in inference).

FIG. 6 shows an attention layer l with a single-stage attention unit according to various aspects. Here, in 604, all (existing) input elements Z_{i=1:L}_{_{i,d}}_{,d=1:P,l-1}, 602, can be combined (e.g., concatenated) by means of the function vec( ). The concatenation vec(Z_{:,:,l}) can then be fed to single-stage attention 606 in order to generate the output vector \tilde{Z}_{:,:,l} according to \tilde{Z}_{:,:,l}=MSA^{osa}(vec(Z_{:,:,l-1}), vec(Z_{:,:,l-1}), vec(Z_{:,:,l-1})) as an intermediate result, and then output the output elements Z_{i=1:L}_{_{i,d}}_{,d=1:P,l}, 608, by applying layer norms dropout, connection skipping, feedforward, etc. (in 607).

By using single-stage attention (MSA^{osa}) with joint input of all input elements Z_{i=1:L}_{_{i,d}}_{,d=1:P,l=0}, it is not necessary for all sensor data to be time series. For example, a sensor data segment

$${x}_{i , d}^{( s )}$$

can also relate to a scalar value. A scalar value can, for example, be a value of a global system parameter (e.g., as a physical variable) (e.g., an initial charge capacity of a battery). For example, as shown in FIG. 6, a sensor data segment

$${x}_{i , d}^{( s )}$$

and thus its input element (input element Z_{3,2,l-1} in the example of FIG. 6) may be missing. This is not possible with two-stage attention since sensor data are then required for each time period (of the same length).

With reference to FIG. 5, according to the transformer architecture, the sequence embeddings generated by the encoder 212-1 Z_{i=1:L}_{_{i,d}}_{,d=1:P,l=L} can then be fed to the decoder 212-2 after L attention layers in the encoder Z_{i=1:L}_{_{i,d}}_{,d=1:P,l=L} and at least one target variable query Q_{τ*,d*}. The target value query Q_{τ*,d*} can represent the temporal position t* (e.g., specifying a start time and an end time) of the time course to be predicted, within the time period and the text description TB of the physical target variable d*. For this purpose, the target variable query Q_{τ*,d*} can be determined, for example using the position representation

$${e}_{τ * , d *}^{t}$$

and the text representation

$${e}_{τ * , d}^{c} ,$$

for example according to

$${Q}_{τ * , d *} = {e}_{τ * , d *}^{t} + {e}_{τ * , d}^{c} .$$

According to various aspects, the decoder 212-2 may be fed one or more target variable queries Q_{n=1:N,t*}_{ₙ}_{,d*}_{ₙ}, each target variable query Q_{n,t*}_{ₙ}_{,d*}_{ₙ} of which may specify the respective temporal position and a respective physical target variable of a time course to be predicted. As described above, the decoder 212-2 can also have multiple attention layers l. The decoder 212-2 can then output the corresponding prediction x_{τ*,d*} of the time course. For this purpose, the decoder 212-2 can, for example, be configured to determine the corresponding prediction x_{i*,d*} by linearly projecting the output elements (e.g., if the number of data points/the duration of the prediction x_{i*,d*} corresponds to the temporal index i*). According to various aspects, the decoder 212-2 can implement an attention unit MSA that uses the temporal position t* as the query and the output elements as the value and as the key to allow any duration of the prediction.

According to various aspects, each attention layer l in the encoder 212-1 and/or in the decoder 212-2 can implement a routing mechanism, like in reference [2]. In the routing mechanism, each attention unit MSA^{osa} is divided into a first subunit

$${MSA}_{1}^{osa}$$

and a second subunit

$${MSA}_{2}^{osa} ,$$

wherein the first subunit

$${MSA}_{1}^{osa}$$

outputs intermediate features B_{1:N,l} according to

$${B}_{1 : N , l} = {MSA}_{1}^{osa} ( {Q}_{1 : N , t {*}_{n} , d {*}_{n}} , vec ( {Z}_{: , : , l - 1} ) , vec ( {Z}_{: , : , l - 1} ) ) ,$$

and wherein the second subunit

$${MSA}_{2}^{osa}$$

uses these intermediate features B_{1:N,l} as the key and as the value according to

$${\tilde{Z}}_{l} = {MSA}_{2}^{osa} ( vec ( {Z}_{: , l - 1} ) , {B}_{1 : N , l} , {B}_{1 : N , l} ) .$$

In contrast to the routing mechanism of reference [2], however, no routing variables (referred to as R_{i,:} in reference [2]) are learned as queries; instead, the one or more target variable queries Q_{n=1:N,t*}_{ₙ}_{,d*}_{ₙ} serve as queries for the first subunit

$${MSA}_{1}^{osa} .$$

Illustratively, the encoder 212-1 and/or the decoder 212-2 may implement a query-based routing mechanism. According to various aspects, the query-based routing mechanism described herein may also be implemented in the encoder 212-1.

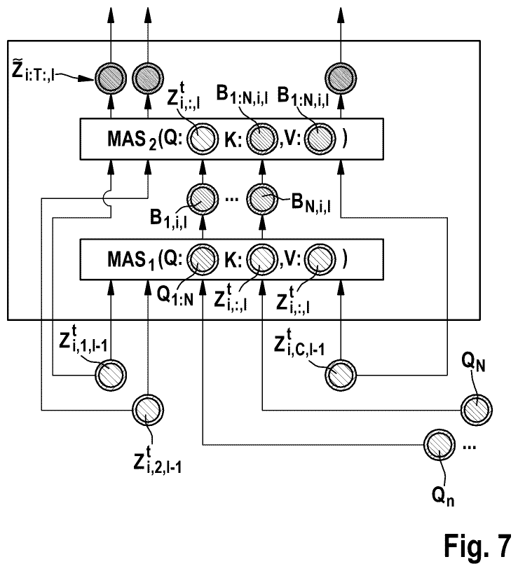

The routing mechanism is shown by way of example in FIG. 7 as an example for a two-stage attention unit. It is understood that this is merely illustrative due to the reduced number of input elements (in this example, the time dimension t) and that the decoder 212-2, like the encoder 212-1, uses single-stage attention, as explained herein.

The query-based routing mechanism in combination with single-stage attention allows for a reduction in the complexity of the machine learning model 212. As a result, it can, for example, be (or have been) trained with reduced computational effort (since, for example, no routing variables need to be learned). Furthermore, by integrating the information about the target variable (by means of the text description and time reference) into the target variable query/queries, better embeddings are generated, leading to higher accuracy of the machine learning model 212. Time series of sensor data can also contain comparatively long time spans so that reducing the complexity of attention leads to increased computational efficiency.

Although various aspects refer to predicting the time course of the physical target variable, it is understood that an anomaly can also be predicted by means of the machine learning model described herein. In one example, the anomaly can also be determined based on the predicted time course of the physical target variable. For example, an anomaly can be detected by determining that the prediction of the time course of the physical variables of the query matches the time course of the physical variables of the input, and the reconstruction error of the input can be evaluated. For example, if the reconstruction error is greater than or equal to a threshold value, the input can be determined to be an anomaly.

What is claimed is:

1. A method for predicting a time course of a physical target variable using a machine learning model, the method the following steps:
providing multivariate sensor data assigned to a time period and including, for each physical variable of a plurality of physical variables, respective sensor data representing a time course of the physical variable within the time period, wherein each physical variable of the physical variables is assigned a respective text description describing the physical variable;
for each physical variable of the plurality of physical variables:
dividing the respective sensor data into a respective plurality of sensor data segments, and
for each sensor data segment of the plurality of sensor data segments:
determining a respective sensor data segment representation representing the sensor data segment and having, independently of a number of data points of the sensor data segment, a predefined dimension, and
determining a respective input element using the respective sensor data segment representation, time-related position information representing a position of the sensor data segment within the time period, and the respective text description of the physical variable;
predicting the time course of the physical target variable using the machine learning model in response to an input of all of the respective input elements and at least one target variable query representing a position of the time course to be predicted, within the time period, and a text description of the physical target variable, into the machine learning model.

2. The method according to claim 1, wherein the respective plurality of sensor data segments of at least one of the physical variables includes at least two sensor data segments with a different number of data points.

3. The method according to claim 1, wherein the time-related position information represents a start time and an end time within the time period.

4. The method according to claim 1, wherein the machine learning model includes a transformer model having an encoder and/or decoder which includes an attention layer to which all of the respective input elements are fed.

5. The method according to claim 1, wherein: (i) the respective sensor data segment representation for a sensor data segment is determined by means of an attention unit having a learned sensor-data-segment-specific parameter vector as the query and the sensor data segment as the key and as the value, and/or (ii) the respective input element is determined using the respective sensor data segment representation, a respective position representation, and the respective text description of the physical variable, wherein the position representation is determined using an attention unit having a learned position-specific parameter vector as the query and the time-related position information as the key and as the value.

6. The method according to claim 1, wherein the machine learning model includes a transformer model including an encoder and/or decoder having one or more attention layers which include an attention unit to which the target variable query is fed.

7. A system, comprising:
a device configured to carry out a technical process;
one or more sensors configured to acquire multivariate sensor data; and
a control device configured to predict a time course of a physical target variable using a machine learning model, by performing the following steps:
providing the multivariate sensor data assigned to a time period and including, for each physical variable of a plurality of physical variables, respective sensor data representing a time course of the physical variable within the time period, wherein each physical variable of the physical variables is assigned a respective text description describing the physical variable;
for each physical variable of the plurality of physical variables:
dividing the respective sensor data into a respective plurality of sensor data segments, and
for each sensor data segment of the plurality of sensor data segments:
determining a respective sensor data segment representation representing the sensor data segment and having, independently of a number of data points of the sensor data segment, a predefined dimension, and
determining a respective input element using the respective sensor data segment representation, time-related position information representing a position of the sensor data segment within the time period, and the respective text description of the physical variable;
predicting the time course of the physical target variable using the machine learning model in response to an input of all of the respective input elements and at least one target variable query representing a position of the time course to be predicted, within the time period, and a text description of the physical target variable, into the machine learning model;
wherein the control unit is configured to control the technical process, taking into account the prediction.

8. A system, comprising:
a data processing unit configured to predict a time course of a physical target variable using a machine learning model, the data processing unit configured to perform the following steps:
providing multivariate sensor data assigned to a time period and including, for each physical variable of a plurality of physical variables, respective sensor data representing a time course of the physical variable within the time period, wherein each physical variable of the physical variables is assigned a respective text description describing the physical variable;
for each physical variable of the plurality of physical variables:
dividing the respective sensor data into a respective plurality of sensor data segments, and
for each sensor data segment of the plurality of sensor data segments:
determining a respective sensor data segment representation representing the sensor data segment and having, independently of a number of data points of the sensor data segment, a predefined dimension, and
determining a respective input element using the respective sensor data segment representation, time-related position information representing a position of the sensor data segment within the time period, and the respective text description of the physical variable;
predicting the time course of the physical target variable using the machine learning model in response to an input of all of the respective input elements and at least one target variable query representing a position of the time course to be predicted, within the time period, and a text description of the physical target variable, into the machine learning model.

9. A non-transitory computer-readable medium on which are stored commands predicting a time course of a physical target variable using a machine learning model, the commands, when executed by a processor, causing the processor to perform the following steps comprising:
providing multivariate sensor data assigned to a time period and including, for each physical variable of a plurality of physical variables, respective sensor data representing a time course of the physical variable within the time period, wherein each physical variable of the physical variables is assigned a respective text description describing the physical variable;
for each physical variable of the plurality of physical variables:
dividing the respective sensor data into a respective plurality of sensor data segments, and
for each sensor data segment of the plurality of sensor data segments:
determining a respective sensor data segment representation representing the sensor data segment and having, independently of a number of data points of the sensor data segment, a predefined dimension, and
determining a respective input element using the respective sensor data segment representation, time-related position information representing a position of the sensor data segment within the time period, and the respective text description of the physical variable;
predicting the time course of the physical target variable using the machine learning model in response to an input of all of the respective input elements and at least one target variable query representing a position of the time course to be predicted, within the time period, and a text description of the physical target variable, into the machine learning model.
